(19) United States
(12) Patent Application Publication
(10) Pub. No.: US 2007/0181178 A1
(43) Pub. Date: Aug. 9, 2007

(54) Electrolyte composition and dye-sensitized solar cells employing the same

(76) Inventors: Byung Hee Sohn, Yongin-si (KR); Jung Gyu Nam, Yongin-si (KR); Sang Cheol Park, Seoul (KR); Jae Gu Yoon, Suwon-si (KR)

Correspondence Address: CANTOR COLBURN, LLP, 55 GRIFFIN ROAD SOUTH, BLOOMFIELD, CT, 06002, US

(21) Appl. No.: 11/519,590

(22) Filed: Sep. 12, 2006

(30) Foreign Application Priority Data
Feb. 8, 2006 (KR) 10-2006-0012037

(51) Int. Cl. H01L 31/00

(52) U.S. Cl. 136/263

(57) ABSTRACT

Disclosed herein is an electrolyte composition useful in a dye-sensitized solar cell. The electrolyte includes a ring compound to which metal cations of an oxidation-reduction derivative are bound, so that the anions of the oxidation-reduction derivative can freely deliver electrons, thereby significantly improving the photoelectric conversion efficiency of the solar cells.

### CROSS-REFERENCE TO RELATED PATENT APPLICATIONS

This application claims priority to Korean Patent Application No. 2006-0012037, filed on Feb. 8, 2006, and all the benefits accruing therefrom under 35 U.S.C. § 119(a), the content of which is incorporated herein in its entirety by reference.

### BACKGROUND OF THE INVENTION

1. Field of the Invention

The present invention relates to an electrolyte and a dye-sensitized solar cell employing the same. More particularly, the present invention relates to an electrolyte having a fill factor (FF) sufficiently high to allow the solar cell to have significantly improved photoelectric conversion efficiency.

2. Description of Related Art

With the depletion of fossil fuels deposits and severer regulations governing carbon dioxide generation, solar cells, which convert photons from the sun (solar light) into electricity without environmental pollution, have been considered a promising solution to the problems of both environmental protection and energy generation.

Dye-sensitized solar cells are a type of photoelectrochemical solar cell that function by extracting energy from light. Dye-sensitized solar cells include, in the active region of the cell, a photosensitive dye molecule capable of absorbing visible light to produce electron-hole pairs, and a transition metal oxide for transferring the produced electrons. Representative dye-sensitized solar cells developed thus far include the solar cells invented by Graetzel et al., in 1991 (U.S. Pat. Nos. 4,927,721 and 5,350,644). The Graetzel cell has a semiconductive electrode made from photosensitive dye-coated nanocrystalline titanium oxide (TiO₂) and a counter electrode (e.g. platinum) with an electrolyte interposed therebetween. Since the advent thereof, dye-sensitized solar cells have attracted keen and extensive attention thanks to the lower production cost relative to the power yielded when compared with silicon solar cells, the environmental friendliness of the production process for such solar cells, and the ability of such solar cells to be fabricated into flexible forms, while maintaining an energy conversion yield as high as that of amorphous silicon solar cells.

With reference to FIG. 1, the operation principle of a typical dye-sensitized solar cell is illustrated in FIG. 1. As seen in FIG. 1, when solar light is absorbed into a semiconductor layer 111 which is chemically coated with dye molecules, electrons of these dye molecules transit from a ground state (D⁺/D) to an excited state (D⁺/D*) to form electron-hole pairs, and electrons in the excited state are injected into the conduction band (CB) of the semiconductor layer. After being injected into the semiconductor layer 111, the electrons transfer to a transparent conductive oxide (TCO) substrate 112 through grain interfaces and then to a counter electrode 114 through an external wire 113 connected to the TCO substrate 112 serving as an electrode. An oxidation-reduction electrolyte 115 is placed between the counter electrode 114 and the semiconductor layer 111. Connected both to the TCO electrode 112 and to the counter electrode 114 in series therebetween, a load is provided to measure short-circuit currents, open-circuit voltages, and fill factors, thereby detecting the energy conversion efficiency of the solar cell.

A solar cell's energy conversion efficiency (η), that is, photoelectric conversion efficiency, is the percentage of power generated (Pₒᵤₜ) relative to light energy absorbed (Pᵢₙ), which is proportional to the quantity of electrons generated upon light absorption, and which is represented by the following equation:

$${Γ}_{⋃} = \frac{{P}_{out}}{{P}_{∈}} = \frac{{I}_{max} \times {V}_{max}}{{P}_{∈}} = \frac{{I}_{sc} \times {V}_{cc} \times FF}{{P}_{∈}}$$

In the equation, FF stands for “fill factor”, which is another defining term in the overall behavior of a solar cell. Also in the equation, Pₒᵤₜ is as defined above, P_{ε} is used interchangeably with Pᵢₙ and is as defined above, Iₘₐₓ is the maximum current from the solar cell, Vₘₐₓ is the maximum voltage from the solar cell, I_{sc} is the short-circuit current which is the output current at zero voltage, and V_{oc} is the open-circuit voltage which is the output voltage at zero current, for the solar cell. The characteristics of the solar cell are improved as the current-voltage curve approaches a rectangular form as seen in FIG. 2.

As an approach to the improvement of photoelectric transformation efficiency, also referred to herein as the photoelectric conversion efficiency, the production of a large number of electrons by increasing either sunlight absorption or the amount of dye applied thereon have each been suggested. Alternatively, the consumption of excited electrons through electron-hole recombination can be prevented to increase the photoelectric transformation efficiency. In order to retain a large amount of photosensitive dye within the electrode, a method is provided for preparing oxide semiconductor particles on a nano-scale. A method of increasing the reflectivity of a platinum electrode or of using micrometer-sized semiconductor oxide photo-scattering particles has been suggested to increase sunlight absorption.

Japanese Pat. Laid-Open Publication No. 2001-266962 discloses an electrolyte composition comprising an aromatic compound which is capable of forming anions of 5-membered heteroaromatic rings containing nitrogen and/or oxygen atoms therein, such as oxazole rings, thiazole rings, imidazole rings, etc., or anions of 6-membered heteroaromatic ring containing nitrogen and/or oxygen atom therein, such as pyridine rings, pyridazine rings, triazine rings, etc. The electrolyte composition is superior in durability and charge transfer ability, so that it can improve photoelectric transformation characteristics. In addition, the electrolyte composition shows low deterioration with time.

However, there always exists a need for additional improvement in the photoelectric transformation efficiency of solar cells, which can be achieved by a technique capable of overcoming the limitations of the conventional techniques. A change in the property of the electrolyte leading to an increase in the number of redox electrons can be important in improving the characteristics of solar cells, such as open circuit voltage (V_{oc}) and fill factor (FF).

### SUMMARY OF THE INVENTION

It is an object of the present invention to provide an electrolyte that is improved with respect to open-circuit voltage and fill factor, thereby assuring a high photoelectric conversion efficiency for a solar cell.

It is another object of the present invention to provide a dye-sensitized solar cell that is high in photoelectric conversion efficiency, employing the electrolyte.

Provided in accordance with an aspect of the present invention is an electrolyte, comprising a ring compound, represented by chemical formula 1, and an oxidation-reduction derivative:

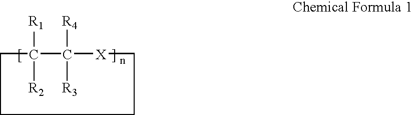

wherein R₁, R₂, R₃ and R₄ may be the same or different and are independently selected from the group consisting of a hydrogen atom; a substituted or non-substituted C₁-C₃₀ alkyl; substituted or non-substituted C₂-C₃₀ alkenyl; a substituted or non-substituted C₂-C₃₀ alkynyl; a substituted or non-substituted C₁-C₃₀ alkoxy; a substituted or non-substituted C₆-C₃₀ arylalkyl; a substituted or non-substituted C₆-C₃₀ aryloxy; a substituted or non-substituted C₁-C₃₀ heteroalkyl; a substituted or non-substituted C₁-C₃₀ heteroalkyloxy; a substituted or non-substituted C₂-C₃₀ heteroaryloxy; a substituted or non-substituted C₂-C₃₀ heteroarylalkyl; and a substituted or repeating unit of non-substituted C₃-C₃₀ alkyloxy;

X is an element with a lone electron pair; and

n is an integer of 4 to 10.

Provided in accordance with another aspect of the present invention is a dye-sensitized solar cell, comprising a semiconductor electrode and a counter electrode, having the electrolyte interposed between the semiconductor electrode and the counter electrode.

Other details of the embodiments of the present invention will be given to the following description of the drawings and the preferred embodiments of the present invention.

### BRIEF DESCRIPTION OF THE DRAWINGS

FIG. 1 is a schematic view illustrating the principle of operation of a general dye-sensitized solar cell;

FIG. 2 is a current-voltage curve of a solar cell;

FIG. 3 is a schematic cross sectional view showing a dye-sensitized solar cell in accordance with an embodiment of the present invention;

FIG. 4 is a plot showing resistances of the electrolytes used in Examples 1 to 3 and the Comparative Example; and

FIG. 5 is a plot showing resistances of the dye-sensitized solar cells prepared in Examples 1 to 3 and the Comparative Example.

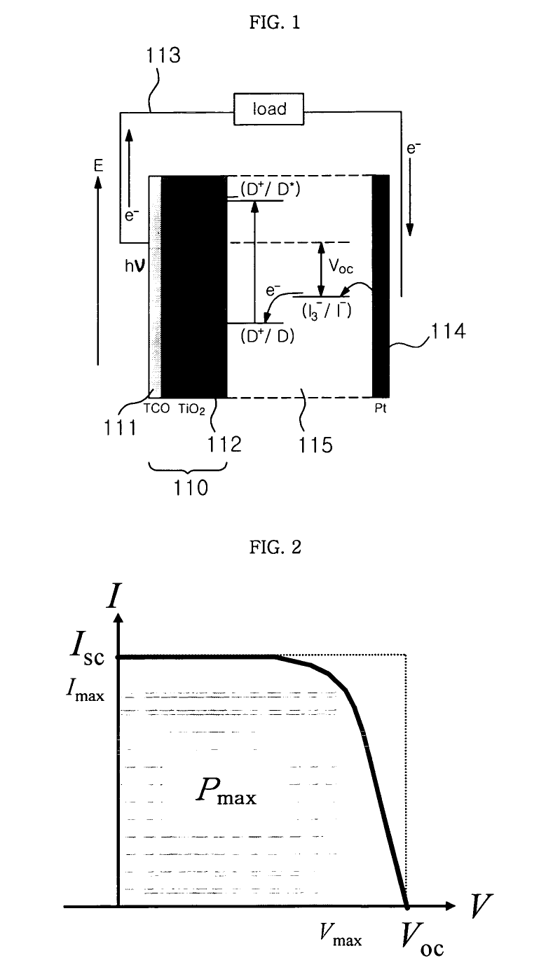

### DESCRIPTION OF THE PREFERRED EMBODIMENTS

Below, a detailed description will be given of the present invention with reference to the accompanying drawings.

It will be understood in the following disclosure of the present invention, that as used herein, the singular forms “a”, “an” and “the” are intended to include the plural forms as well, unless the context clearly indicates otherwise. It will be further understood that the terms “comprise”, “comprises”, and “comprising,” when used in this specification, specify the presence of stated features, integers, steps, operations, elements, components, and combination of the foregoing, but do not preclude the presence and/or addition of one or more other features, integers, steps, operations, elements, components, groups, and combination of the foregoing.

It will be understood that when an element is referred to as being “on” another element, it can be directly on the other element or intervening elements may be present therebetween. In contrast, when an element is referred to as being “disposed on” another element, the elements are understood to be in at least partial contact with each other, unless otherwise specified. Spatially relative terms, such as “between”, “in between” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. The device may be otherwise oriented (rotated 90 degrees, inverted, or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

After being oxidized as a result of electron transition to an excited state (D⁺/D*) upon photon adsorption, photosensitive dye molecules receive the electrons provided in the course of the oxidation of iodide ions (I₃⁻/I⁻) within an electrolyte. In turn, I⁻ ions are reduced by the electrons at the counter electrode. At this time, the electrolyte plays a certain role in transferring electrons from the counter electrode to the dye molecules through the oxidation and reduction of I⁻/I₃⁻. In a solar cell, the open circuit voltage (V_{oc}) is determined by the difference between the Fermi energy (E_{F}) of the metal oxide and the redox potential of the electrolyte while the fill factor (FF) is affected by the series resistance.

An electrolyte comprising a cyclic compound, represented by the following chemical formula 1, and an oxidation-reduction derivative is provided for improving characteristics of both the open-circuit voltage and the fill factor, thereby improving the photoelectric conversion efficiency (η).

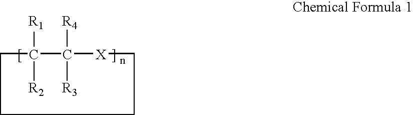

wherein R₁, R₂, R₃, and R₄ may be the same or different and are independently selected from the group consisting of a hydrogen atom; a substituted or non-substituted C₁-C₃₀ alkyl; substituted or non-substituted C₂-C₃₀ alkenyl; a substituted or non-substituted C₂-C₃₀ alkynyl; a substituted or non-substituted C₁-C₃₀ alkoxy; a substituted or non-substituted C₆-C₃₀ arylalkyl; a substituted or non-substituted C₆-C₃₀ aryloxy; a substituted or non-substituted C₁-C₃₀ heteroalkyl; a substituted or non-substituted C₁-C₃₀ heteroalkyloxy; a substituted or non-substituted C₂-C₃₀ heteroaryloxy; a substituted or non-substituted C₂-C₃₀ heteroarylalkyl; and a substituted or repeating unit of non-substituted C₃-C₃₀ alkyloxy;

X is an element with a lone electron pair; and

n is an integer from 4 to 10. Where R₁, R₂, R₃, or R₄ is substituted, the substituent can be a halogen or a C₁-C₁₈ organic group, in which the organic group can be saturated or unsaturated, can include heteroatoms where desired, and is selected such that the desired properties of the cyclic compound are not significantly adversely affected by the presence of the substituent.

In the electrolyte, metal salts of the oxidation-reduction derivative are neither simply dispersed nor mixed, but are dissociated into metal cations and anions. The metal cations form coordination bonds with the lone pairs and can be captured within the cyclic compounds, so that the anions of the oxidation-reduction derivative can freely deliver electrons, leading not only to a reduction in the resistance of the electrolyte which can improve the fill factor, but also to an increase in the number of electrons within the conduction band of the semiconductor layer to improve the open-circuit voltage. Thus, in an embodiment, a method of improving the photoelectric conversion efficiency of a dye-sensitized solar cell includes combining a cyclic compound as disclosed herein and an electrolyte, and disposing the electrolyte between the electrodes of a solar cell.

In Chemical Formula 1, the element (X) with a lone electron pair is selected from the group consisting of —O—, —S—, —NR′— (where R′ is a hydrogen atom or —CH₃), and a combination comprising at least one of the foregoing elements.

The cyclic compound represented by Chemical Formula 1 may be selected for compatibility of size and/or function depending on the iodide salt used as the oxidation-reduction derivative. Specifically, for an alkali metal iodide salt, the cyclic compound may be a crown ether selected for specificity of binding with the particular alkali metal cation of the alkali metal iodide used, such as for example 12-crown-4 when using lithium iodide, 15-crown-5 when using sodium iodide, or 18-crown-6 when using potassium iodide.

In the electrolyte, the cyclic compound is used in an amount of 0.001 to 5 parts by weight, based on 100 parts by weight of the oxidation-reduction derivative. When the content of the cyclic compound is below 0.001 parts by weight, the electron transfer reaction does not proceed efficiently and low voltage is obtained. On the other hand, a content of the cyclic compound exceeding 5 parts by weight results in an increase in voltage, but also results in a significant decrease in current.

When functioning to produce I⁻ and I₃⁻ ions in the electrolyte, the oxidation-reduction derivative includes an iodide salt and iodine (I₂). I⁻ and I₃⁻ ions coexist, providing for a reversible reaction.

Examples of iodide salts useful in the present invention include, but are not limited to, lithium iodide, sodium iodide, potassium iodide, magnesium iodide, copper iodides, silicon iodide, manganese iodides, barium iodide, molybdenum iodides, calcium iodide, iron iodides, cesium iodide, zinc iodide, and mercury iodide. Any metal salt having any oxidation state may be used if capable of producing I⁻ and I₃⁻ ions.

In addition to the metal salts, the iodide salt may further comprise a liquid phase of iodide, such as ammonium iodide, methyl iodide, methylene iodide, ethyl iodide, ethylene iodide, isopropyl iodide, isobutyl iodide, benzyl iodide, benzoyl iodide, aryl iodides, and imidazolium iodide, but are not limited thereto.

Preferably, the iodide salt is employed in an amount of 100 to 3,000 parts by weight based on 100 parts by weight of iodine (I₂). If the content of the iodide salt is less than 100 parts by weight, the reaction does not proceed for insufficient iodide salt. On the other hand, more than 3,000 parts by weight interferes with electron flow and in turn causes a decrease in the current.

Optionally, the electrolyte of the present invention may further comprise an organic solvent. Examples of organic solvents useful in the present invention include, but are not limited to, acetonitrile, ethylene glycol, butanol, isobutyl alcohol, isopentyl alcohol, isopropyl alcohol, ethyl ether, dioxane, tetrahydrofuran, n-butyl ether, n-propyl ether, isopropyl ether, acetone, methylethylketone, methylbutylketone, isobutylketone, ethylene carbonate, diethyl carbonate, propylene carbonate, dimethyl carbonate, ethyl methyl carbonate, methyl propyl carbonate, methyl isopropyl carbonate, ethyl propyl carbonate, butylene carbonate, γ-butyrolactone, N-methyl-2-pyrrolidone, and 3-methoxypropionitrile, or a combination comprising at least one of the foregoing organic solvents.

An organic solvent is not indispensable for the electrolyte of the present invention. For example, when an iodide salt in a liquid phase is used, such as imidazolium iodide, no organic solvent is required.

In another aspect, a dye-sensitized solar cell employing the above-described electrolyte is provided.

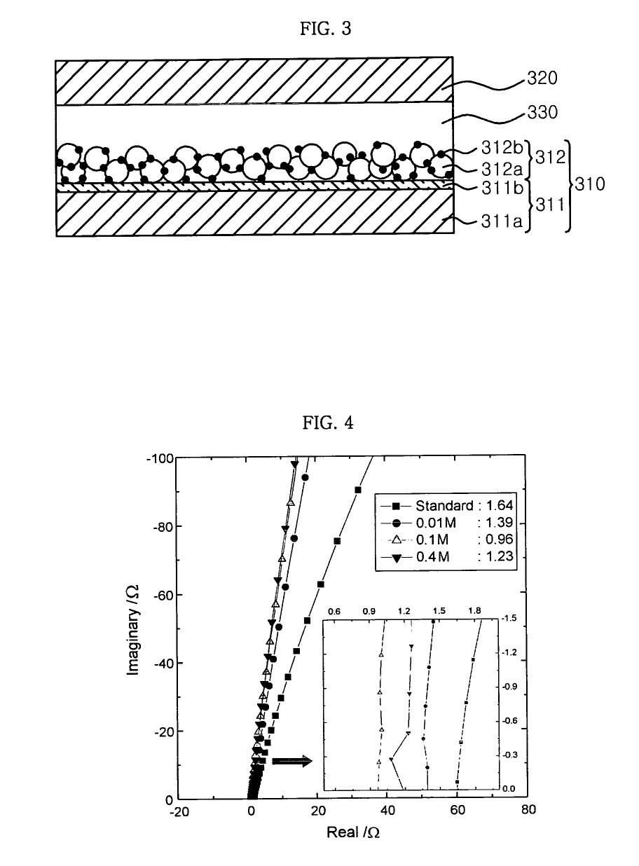

Referring to FIG. 3, a schematic view is provided, showing the fundamental structure of a dye-sensitized solar cell. As seen in FIG. 3, the dye-sensitized solar cell comprises a semiconductor electrode 310 and a counter electrode 320, with an electrolyte 330 disposed therebetween. The semiconductor electrode includes a transparent conductive oxide substrate 311 and a semiconductor layer 312 disposed on the transparent conductive oxide substrate 311. Filling the space between the semiconductor electrode 310 and the counter electrode 320, the electrolyte 330 contains the above-mentioned components (i.e., the cyclic compound, the oxidation-reduction derivative, and optional organic solvent), and is uniformly dispersed within the semiconductor layer 311 and in at least partial contact with each of semiconductor electrode 310 and counter electrode 320.

The transparent conductive oxide substrate 311 comprises a substrate 311a coated with a conductive material 311b. If transparent, the substrate 311a is not specifically limited. For example, transparent inorganic substrates, such as quartz and glass, or transparent plastic substrates, such as polyethylene terephthalate (“PET”), polyethylene naphthalate (“PEN”), polycarbonate, polystyrene, polypropylene, polyimide, and the like, may be used. As the conductive material 311b applied onto the substrate, indium tin oxide (“ITO”), fluorine-doped tin oxide (“FTO”), indium oxide, zinc oxide, sulfur oxide, fluorine oxide or a mixture thereof, such as ZnO—Ga₂O₃, ZnO—Al₂O₃, SnO₂—Sb₂O₃, etc. may be used.

As for the semiconductor layer 312, it comprises a metal oxide 312a with dye 311b adsorbed thereon. The metal oxide 312a may be selected from the group consisting of titanium oxide, niobium oxide, indium oxide, tungsten oxide, tin oxide, zinc oxide, and combinations thereof. Preferable is titanium oxide (TiO₂).

The metal oxide desirably has a large surface area in order to both adsorb a large quantity of the dye thereon to better absorb sunlight, and to provide improved surface compatibility with the electrolyte layer. Thus, the metal oxide is desirably in the form of nano materials, such as quantum dots, nano dots, nano tubes, nano wires, nano belts, or nano particles.

The semiconductor layer 312 may be a monolayer structure or a bilayer structure made from two kinds of metal oxide particles having different particle sizes (i.e., average diameters). In a specific embodiment, the semiconductor layer 312 is a bilayer structure in which metal oxide particles having a particle size of 7 to 20 nm and a particle size of 200 to 400 nm are each formed into corresponding layers having thicknesses of 5 to 20 μm and 4 to 10 μm, respectively.

When sunlight is absorbed into the dye 312b applied to the surface of semiconductor layer, electrons of the dye molecules jump from a ground state to an excited state, resulting in the formation of electron-hole pairs. After being injected into the conduction band of the semiconductor layer of the metal oxide, the excited electrons migrate to the electrode, generating an electromotive force.

The dye possesses charge separation ability and photosensitivity. Any dye generally useful in a solar cell can be used as the dye 312b, without restriction. Specifically, a ruthenium complex is a useful dye. Additional dyes that can be used include, xanthine-based dyes, such as rhodamine B, rose bengal, eosin, erythrosine, and the like; cyanin-based dyes, such as quioncyanin, cryptocyanin, and the like; basic dyes, such as phenosafranin, methylene blue, and the like; porphyrin-based dyes, such as chlorophyll, zinc porphyrin, magnesium porphyrin, and the like; and other dyes such as azo dyes, phthalocyanine compounds, Ru trisbipyridyl complexes, anthraquionone dyes, and polycyclic quinine dye. Combinations comprising at least one of the foregoing dyes may also be used. Exemplary ruthenium complexes that may be used are represented by RuL₂(SCN)₂, RuL₂(H₂O)₂, RuL₃, or RuL₂ (wherein L can be 2,2′-bipyridyl-4,4′-dicarboxylate).

Any conductive material may be used as the counter electrode 320. Even an insulating material can be used as the counter electrode 320 if it has a conductive layer on a side facing the semiconductor electrode. However, the electrode is required to be electrochemically stable. Specifically useful electrodes include platinum, gold, or carbon electrodes.

In the counter electrode, the side facing the transparent electrode has a large surface area with the aim of improving the catalytic oxidation/reduction effects. In this regard, it is desired that the counter electrode have a microstructure on the side facing the transparent electrode. For example, in an embodiment, the counter electrode is made from platinum black rather than platinum itself. Where carbon is used, the counter electrode is desirably porous. Platinum black can be prepared using an anodizing method or through treatment with chloroplatinic acid. Porous carbon can be obtained by sintering carbon microparticles or organic polymers.

The fabrication of the dye-sensitized solar cell is not specifically limited, but may employ any suitable fabrication method without restriction.

A better understanding of the present invention may be obtained through the following examples, which are intended to be illustrative, and should not be construed as limiting thereto.

### EXAMPLE 1

A glass substrate was sputtered with fluorine-doped tin oxide (FTO), and then coated with a paste of TiO₂ particles having a mean particle size of 9 nm and using a screen printing method, followed by drying at 70° C. for 30 min. Subsequently, a paste of TiO₂ particles having a mean particle size of 300 nm was applied to the glass substrate in the same manner, and dried. In an electric furnace, the resulting glass substrate was heated to 450° C. at a rate of 3° C./min in an air atmosphere, maintained at that temperature for 30 min, and then cooled at the same rate as used in heating the substrate, to form a metal oxide having a porous TiO₂ bilayer structure of approximately 30 μm total thickness.

Separately, platinum was sputtered on an indium tin oxide (ITO)-coated glass substrate to provide a counter electrode. The glass substrate was drilled to form small pores about 0.75 mm in diameter and uniformly spaced. A polymeric film (SURLYN®, Du Pont) of about 40 micrometers thickness was placed as a spacer between the counter electrode and the semiconductor electrode, and the two electrodes were attached onto the polymeric film by heating the assembled electrodes with the sheet between on a heating plate at about 100 to 140° C. under a pressure of about 1 to 3 atm (about 0.1 to 0.3 MPa).

Afterwards, an electrolyte was injected through the small pores formed in the anode into the space between the two electrodes to complete a dye-sensitized solar cell. The electrolyte was an I₃⁻/I⁻ solution containing 0.6 M 1-methyl-3-ethyl imidazole, 0.4 M KI, 0.2 M I₂, 0.1 M t-butyl pyridine, and 0.01 M 18-crown-6 in a solution in 1-methoxypropionitrile.

### EXAMPLES 2 AND 3

The same procedure as in Example 1 was conducted to prepare dye-sensitized solar cells, with the exception that the 18-crown-6 was used in concentrations of 0.1 M and 0.4 M, for Examples 2 and 3, respectively.

### COMPARATIVE EXAMPLE

A dye-sensitized solar cell was fabricated in the same manner as in Example 1, with the exception that no 18-crown-6 was used.

### EXPERIMENTAL EXAMPLE 1

### Measurement of Electrolyte for Resistance

The electrolytes used in Examples 1 to 3 and the Comparative Example were measured for resistance only. In a crimping machine, a stainless steel electrode 1.3 mm in diameter and a separator were sequentially placed on a lower cap, followed by the injection of 0.15 cc of the electrolyte. As a counter electrode, a stainless steel electrode 1.3 mm in diameter was positioned over the separator. An upper cap with a gasket inserted into it was located over the lower cap with the aid of a spring-type spacer. The lower cap and the gasket-inserted upper cap were crimped by air compression to prepare a coin cell. The coin cell was mount on a frequency response analyzer and measured for impedance under conditions of base DC voltage 0, AC width 10 mV, and frequency scan range 0.1 to 10⁶ Hz, and the results are shown in FIG. 4.

With reference to FIG. 4, the electrolytes are found to have lower resistance when they comprise a ring compound containing an element having a lone electron pair than when they have no such ring compound.

### EXPERIMENTAL EXAMPLE 2

### Measurement of Dye-Sensitized Solar Cell for Resistance

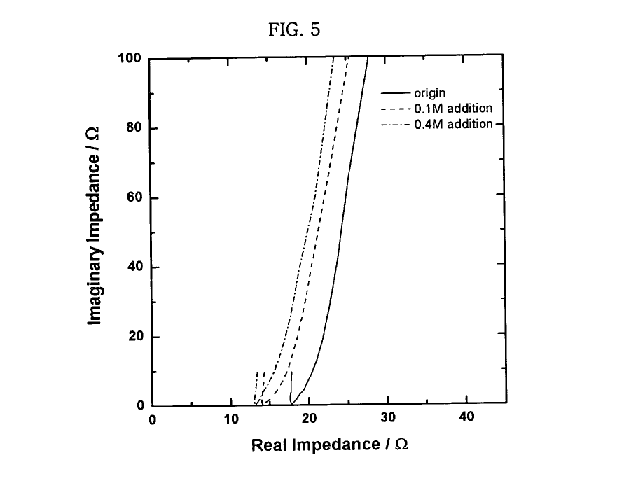

The dye-sensitized solar cells prepared in Examples 1 to 3 and the Comparative Example were measured for resistance with the aid of an impedance analyzer (Solatron Analytical), and the results are shown in FIG. 5

As apparent from data of FIG. 5, the presence of the ring compound allowed the solar cells to significantly decrease in resistance. The resistance was decreased in a dose-dependent pattern to the saturation at a certain amount of the ring compound.

### EXPERIMENTAL EXAMPLE 2

### Measurement of Dye-Sensitized Solar Cell for Photoelectric Conversion Efficiency

In order to analyze the dye-sensitized solar cells prepared in Examples 1 to 3 and the Comparative Example for photoelectric conversion efficiency, their photovoltages and photocurrents were measured.

A xenon lamp (Oriel, 01193) was used as a light source. The irradiance conditions for AM 1.5 standard was corrected with a standard solar cell (Frounhofer Institute Solare Engeriessysteme, Certificate No. C-ISE369, Type of material: Mono-Si+KG filter). After being calculated from photocurrent-voltage curves, current densities (I_{sc}), open circuit voltages (V_{oc}) and fill factors (FF) were used to obtain photoelectric conversion efficiencies (ηₑ) of the solar cells through the following formula. The results are summarized in Table 1, below.

ηₑ=(V_{oc}·I_{sc}·FF)/(P_{inc})

wherein P_{inc} is expressed in units of 100 mw/cm² (1 sun)

TABLE 1

| Example Nos. | I_{sc}(mA/cm²) | V_{oc}(mV) | FF | ηₑ(%) |
|---|---|---|---|---|
| Example 1 | 9.046 | 696.795 | 0.594 | 3.747 |
| Example 2 | 9.054 | 691.850 | 0.601 | 3.766 |
| Example 3 | 8.508 | 696.869 | 0.623 | 3.687 |
| Comparative Example | 9.068 | 672.50 | 0.585 | 3.566 |

Taken together, the data of Table 1, obtained from Examples 1 to 3 and the Comparative Example, demonstrate that the dye-sensitized solar cells employing the electrolyte according to the present invention have improved open-circuit voltage (V_{oc}) and fill factor (FF), thus showing high photoelectric conversion efficiencies. The photoelectric conversion efficiency η of a cell prepared is thereby improved by greater than or equal to 0.1% of the total efficiency of the solar cell.

As described hereinbefore, the electrolyte of the present invention has a ring compound to which metal cations of an oxidation-reduction derivative are bound, so that the anions of the oxidation-reduction derivative can freely deliver electrons, thereby significantly improving the photoelectric conversion efficiency of the solar cells.

Although a specific embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. An electrolyte, comprising a ring compound, represented by chemical formula 1, and an oxidation-reduction derivative: 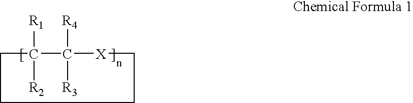
wherein R₁, R₂, R₃ and R₄ may be the same or different and are independently selected from the group consisting of a hydrogen atom; a substituted or non-substituted C₁-C₃₀ alkyl; substituted or non-substituted C₂-C₃₀ alkenyl; a substituted or non-substituted C₂-C₃₀ alkynyl; a substituted or non-substituted C₁-C₃₀ alkoxy; a substituted or non-substituted C₆-C₃₀ arylalkyl; a substituted or non-substituted C₆-C₃₀ aryloxy; a substituted or non-substituted C₁-C₃₀ heteroalkyl; a substituted or non-substituted C₁-C₃₀ heteroalkyloxy; a substituted or non-substituted C₂-C₃₀ heteroaryloxy; a substituted or non-substituted C₂-C₃₀ heteroarylalkyl; and a substituted or repeating unit of non-substituted C₃-C₃₀ alkyloxy;
X is an element with a lone electron pair; and
n is an integer from 4 to 10.

2. The electrolyte as defined in claim 1, wherein X is selected from the group consisting of —O—, —S—, —NR′—, or a combination comprising at least one of the foregoing, and wherein R′ is a hydrogen atom or CH₃.

3. The electrolyte as defined in claim 1, wherein the ring compound is selected from the group consisting of 18-crown-6, 15-crown-5 and 12-crown-4.

4. The electrolyte as defined in claim 1, wherein the ring compound is used in an amount of 0.001 to 5 parts by weight based on 100 parts by weight of the oxidation-reduction derivative.

5. The electrolyte as defined in claim 1, wherein the oxidation-reduction derivative comprises an iodide salt and iodine (I₂).

6. The electrolyte as defined in claim 5, wherein the iodide salt is a metal salt selected from the group consisting of lithium iodide, sodium iodide, potassium iodide, magnesium iodide, copper iodides, silicon iodide, manganese iodides, barium iodide, molybdenum iodides, calcium iodide, iron iodides, cesium iodide, zinc iodide and mercury iodide.

7. The electrolyte as defined in claim 5, wherein the iodide salt is present in an amount of 100 to 3,000 parts by weight based on 100 parts by weight of iodine (I₂).

8. The electrolyte as defined in claim 5, wherein the iodide salt comprises, in addition to the metal salt, a compound selected from the group consisting of ammonium iodide, methyl iodide, methylene iodide, ethyl iodide, ethylene iodide, isopropyl iodide, isobutyl iodide, benzyl iodide, benzoyl iodide, aryl iodide, imidazolium iodide, or a combination comprising at least one of the foregoing compounds.

9. The electrolyte as defined in claim 1, further comprising an organic solvent.

10. The electrolyte as defined in claim 9, wherein the organic solvent is selected from the group consisting of acetonitrile, ethylene glycol, butanol, isobutyl alcohol, isopentyl alcohol, isopropyl alcohol, ethyl ether, dioxane, tetrahydrofuran, n-butyl ether, propyl ether, isopropyl ether, acetone, methyl ethyl ketone, methyl butyl ketone, isobutyl ketone, ethylene carbonate, diethyl carbonate, propylene carbonate, dimethyl carbonate, ethyl methyl carbonate, γ-butyrolactone, N-methyl-2-pyrrolidone, 3-methoxypropionitrile, or a combination comprising at least one of the foregoing organic solvents.

11. A dye-sensitized solar cell comprising the electrolyte of claim 1.

12. A dye-sensitized solar cell, comprising a semiconductor electrode, a counter electrode, and an electrolyte comprising
a ring compound, represented by chemical formula 1, and an oxidation-reduction derivative: 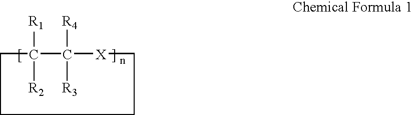
wherein R₁, R₂, R₃ and R₄ may be the same or different and are independently selected from the group consisting of a hydrogen atom; a substituted or non-substituted C₁-C₃₀ alkyl; substituted or non-substituted C₂-C₃₀ alkenyl; a substituted or non-substituted C₂-C₃₀ alkynyl; a substituted or non-substituted C₁-C₃₀ alkoxy; a substituted or non-substituted C₆-C₃₀ arylalkyl; a substituted or non-substituted C₆-C₃₀ aryloxy; a substituted or non-substituted C₁-C₃₀ heteroalkyl; a substituted or non-substituted C₁-C₃₀ heteroalkyloxy; a substituted or non-substituted C₂-C₃₀ heteroaryloxy; a substituted or non-substituted C₂-C₃₀ heteroarylalkyl; and a substituted or repeating unit of non-substituted C₃-C₃₀ alkyloxy;
X is an element with a lone electron pair; and
n is an integer from 4 to 10,
wherein the electrolyte is disposed between the semiconductor electrode and the counter electrode.

13. A method of improving the photoelectric efficiency of a dye-sensitized solar cell comprising combining
an electrolyte comprising an oxidation-reduction derivative, and
a ring compound, represented by chemical formula 1, 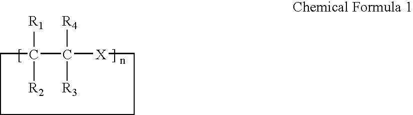
wherein, R₁, R₂, R₃ and R₄ may be the same or different and are independently selected from the group consisting of a hydrogen atom; a substituted or non-substituted C₁-C₃₀ alkyl; substituted or non-substituted C₂-C₃₀ alkenyl; a substituted or non-substituted C₂-C₃₀ alkynyl; a substituted or non-substituted C₁-C₃₀ alkoxy; a substituted or non-substituted C₆-C₃₀ arylalkyl; a substituted or non-substituted C₆-C₃₀ aryloxy; a substituted or non-substituted C₁-C₃₀ heteroalkyl; a substituted or non-substituted C₁-C₃₀ heteroalkyloxy; a substituted or non-substituted C₂-C₃₀ heteroaryloxy; a substituted or non-substituted C₂-C₃₀ heteroarylalkyl; and a substituted or repeating unit of non-substituted C₃-C₃₀ alkyloxy;
X is an element with a lone electron pair; and
n is an integer from 4 to 10, and
wherein the electrolyte is disposed between the semiconductor electrode and the counter electrode of a dye, and wherein the photoelectric conversion efficiency η of the cell is improved by greater than or equal to 0.1% in total efficiency when measured under irradiance conditions according to AM 1.5 standard.
